(19) United States
(12) Patent Application Publication
(10) Pub. No.: US 2020/0028033 A1
(43) Pub. Date: Jan. 23, 2020

(54) DEVICES INCLUDING GREEN-EMITTING PHOSPHORS

(71) Applicant: GENERAL ELECTRIC COMPANY, Schenectady, NY (US)

(72) Inventors: Samuel Joseph CAMARDELLO, Ballston Lake, NY (US); Anant Achyut SETLUR, Niskayuna, NY (US)

(21) Appl. No.: 16/124,520

(22) Filed: Sep. 7, 2018

Related U.S. Application Data
(60) Provisional application No. 62/640,150, filed on Mar. 8, 2018.

(51) Int. Cl. H01L 33/50; C09K 11/77; C09K 11/88; C09K 11/61

(52) U.S. Cl. CPC H01L 33/502; H01L 33/504; C09K 11/7713; C09K 11/617; C09K 11/886; C09K 11/7706; C09K 11/771

(57) ABSTRACT

A device including an LED light source optically coupled to a phosphor material including a green-emitting phosphor selected from the group consisting of compositions of (A1)-(A70), and combinations thereof.

### CROSS-REFERENCE TO RELATED APPLICATIONS

This application relates to, and claims priority from a provisional U.S. patent application having docket number 323772-1 and Ser. No. 62/640,150, entitled “DEVICES INCLUDING GREEN-EMITTING PHOSPHORS”, filed on Mar. 8, 2018, which application is hereby incorporated by reference.

### BACKGROUND

Current display device technology relies on liquid crystal displays (LCDs), which is one of the most widely used flat panel displays for industrial and residential applications. However, next-generation devices that will have low energy consumption, compact size, and high brightness, requiring improved color gamut (NTSC ratio).

LED backlight units (BLU) for use in displays are based on a combination of a blue LED, a green phosphor and a red phosphor. The color gamut of LED BLUs is largely determined by the choice of phosphors. Red phosphor K₂SiF₆:Mn⁴⁺ has a peak with full width at half maximum (FWHM) of 6 to 8 nm yields high color reproducibility in correspondence with the relative intensity of the emission peak. Green phosphor, β-SiAlON: Eu²⁺ has a half width of 46 to 52 nm and has peak wavelength of 534 nm, which is not a pure green but greenish yellow in color. Accordingly, there is also a need for new green emitting phosphors that efficiently absorb blue radiation, provide high quantum efficiency, and have improved color rendering.

### BRIEF DESCRIPTION

Briefly, in one aspect, the present disclosure relates to a device including an LED light source optically coupled to a phosphor material including a green-emitting phosphor selected from the group consisting of compositions (A1)-(A70) and combinations thereof.

Another aspect is a lighting apparatus including the device. Yet another aspect is a backlight apparatus including the device.

### DRAWINGS

These and other features, aspects, and advantages of the present disclosure will become better understood when the following detailed description is read with reference to the accompanying drawings in which like characters represent like parts throughout the drawings, wherein:

FIG. 1 is a schematic of a device, in accordance with one embodiment of the disclosure;

FIG. 2 is a schematic cross-sectional view of a lighting apparatus, in accordance with one embodiment of the disclosure;

FIG. 3 is a schematic cross-sectional view of a lighting apparatus, in accordance with another embodiment of the disclosure;

FIG. 4 is a schematic cross-sectional view of a lighting apparatus, in accordance with yet another embodiment of the disclosure; and

FIG. 5 is a schematic perspective view of a backlight apparatus, in accordance with one embodiment of the disclosure.

### DETAILED DESCRIPTION

In the following specification and the claims, the singular forms “a”, “an” and “the” include plural referents unless the context clearly dictates otherwise. As used herein, the term “or” is not meant to be exclusive and refers to at least one of the referenced components being present and includes instances in which a combination of the referenced components may be present, unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “about” and “substantially” is not limited to the precise value specified. In some instances, the approximating language may correspond to the precision of an instrument for measuring the value.

Devices according to the present disclosure include an LED light source optically coupled to a phosphor material including a green-emitting phosphor selected from the group consisting of compositions (A1)-(A70) and combinations thereof. Most of these compositions (A1)-(A70) are minerals that may emit green light, and referred to as green-emitting phosphors. In some embodiments, one or more compositions (A1)-(A70) are hydrated. The one or more compositions (A1)-(A70) may vary in the degree of hydration.

The compositions of groups (A1)-(A15) represent formulae, and each formula represents various possible minerals that may be green-emitting phosphors. A formula may include a green-emitting phosphor of respective formula or a combination of possible green-emitting phosphors. The square brackets in formulae (A25), (A60), (A64) and (A66) indicate that at least one of the elements, is present in the phosphor, and any combination of two or more thereof may be present. For example, the formula [K,Ba,Ca]₂(UO₂)₂Si₅O₁₃—H₂O encompasses at least one of K, Ba, Ca or any combination of two or more of K, Ba, or Ca. Furthermore, some compositions such as (A70) show “U” after the colon “:” in the composition. This representation indicates that the composition is doped with U (uranium) and may be referred to as U-doped phosphor.

In some embodiments, the green-emitting phosphor is selected from the group consisting of compositions of formula (A1). Examples of the green-emitting phosphor of formula (A1) include Na₂(UO₂)₂(AsO₄)₂5H₂O, K₂(UO₂)₂(AsO₄)₂-6H₂O, Ba(UO₂)₂(AsO₄)₂—(10-12)H₂), Co(UO₂)₂(AsO₄)₂-8H₂O, Cu(UO₂)₂(AsO₄)₂-8H₂O, Cu(UO₂)₂(AsO₄)₂-12H₂O, Zn(UO₂)₂(AsO₄)₂-10H₂O, Mg(UO₂)₂(AsO₄)₂-(4-8)H₂), Mg(UO₂)₂(AsO₄)₂-(10-12)H₂), Ca(UO₂)₂(AsO₄)₂-8H₂), Ca(UO₂)₂(AsO₄)₂-10H₂), Ba(UO₂)₂(AsO₄)₂-8H₂), Ba(UO₂)₂(AsO₄)₂-(10-12)H₂), (NH₄,H₃O)₂(UO₂)₂(AsO₄, PO₄)₂-6H₂), (NH₄)₂(UO₂)₂(PO₄)₂-6H₂), (H₃O)₂(UO₂)₂(PO₄)₂-6H₂O, Na₂(UO₂)₂(PO₄)₂-(6-8)H₂), Na₂(UO₂)₂(PO₄)₂-(10-16)H₂O, K₂(UO₂)₂(PO₄)₂-6H₂), Fe(UO₂)₂(PO₄)₂-8H₂), Mg(UO₂)₂(PO₄)₂-8H₂), Mg(UO₂)₂(PO₄)₂-10H₂O, Ca(UO₂)₂(PO₄)₂-(2-6)H₂), Ca(UO₂)₂(PO₄)₂-11H₂O, Ba(UO₂)₂(PO₄)₂-6H₂O, Ba(UO₂)₂(PO₄)₂-8H₂), Ba(UO₂)₂(PO₄)₂-12H₂O, Pb(UO₂)₂(PO₄)₂-4H₂O, Na₂(UO₂)₂(VO₄)₂-6H₂), K₂(UO₂)₂(VO₄)₂-(1-3)H₂O, Ca(UO₂)₂(VO₄)₂-3H₂), or a combination thereof.

In some embodiments, the green-emitting phosphor is selected from the group consisting of compositions of formula (A2). Examples of the green-emitting phosphor of formula (A2) include K(UO₂)(SO₄)(OH)—H₂O, Na(UO₂)(SO₄)(OH)—2H₂O, or a combination thereof. In some embodiments, the green-emitting phosphor is selected from the group consisting of compositions of formula (A3). Examples of the green-emitting phosphor of formula (A3) include K₄(UO₂)(CO₃)₃, Na₄(UO₂)(CO₃)₃, Na₂Ca(UO₂)(CO₃)₃-6H₂O, Mg₂(UO₂)(CO₃)₃-18H₂O, CaMg(UO₂)(CO₃)₃-12H₂O, Ca₂(UO₂)(CO₃)₃—11H₂O, or a combination thereof. In some embodiments, the green-emitting phosphor is selected from the group consisting of compositions of formula (A4). Examples of the green-emitting phosphor of formula (A4) include Ca(UO₂)₄(AsO₄)₂(OH)₄—6H₂O, Pb(UO₂)₄(PO₄)₂(OH)₄—7H₂O, or a combination thereof.

In some embodiments, the green-emitting phosphor is selected from the group consisting of compositions of formula (A5). Examples of the green-emitting phosphor of formula (A5) include K₂(UO₂)₆O₄(OH)₆-7H₂O, Ca(UO₂)₆O₄(OH)₆-8H₂O, Ba(UO₂)₆O₄(OH)₆-8H₂O, or a combination thereof. In some embodiments, the green-emitting phosphor is selected from the group consisting of compositions of formula (A6). Examples of the green-emitting phosphor of formula (A6) include (NH₄)₂(UO₂)(SO₄)₂—2H₂O, Na₂(UO₂)(SO₄)₂—3H₂O, or a combination thereof. In some embodiments, the green-emitting phosphor is selected from the group consisting of compositions of formula (A7). Examples of the green-emitting phosphor of formula (A7) include Al(UO₂)₂(AsO₄)₂(F,OH)—6.5H₂O, Al(UO₂)₂(VO₄)₂(OH)—8H₂O, Al(UO₂)₂(VO₄)₂(OH)—11H₂O, Al(UO₂)₂(PO₄)₂(OH)—8H₂O, or a combination thereof. In some embodiments, the green-emitting phosphor is selected from the group consisting of compositions of formula (A8). Examples of the green-emitting phosphor of formula (A8) include Co₂(UO₂)₆(SO₄)₃(OH)₁₀-16H₂O, Ni₂(UO₂)₆(SO₄)₃(OH)₁₀-16H₂O, Na₄(UO₂)₆(SO₄)₃(OH)₁₀-4H₂O, or a combination thereof. In some embodiments, the green-emitting phosphor is selected from the group consisting of compositions of formula (A9). Examples of the green-emitting phosphor of formula (A9) include Pb₂(UO₂)₃O₂(PO₄)₂—5H₂O, Ca₂(UO₂)₃O₂(PO₄)₂—7H₂O, or a combination thereof. In some embodiments, the green-emitting phosphor is selected from the group consisting of compositions of formula (A10). Examples of the green-emitting phosphor of formula (A10) include Ba(UO₂)₃(SeO₃)₂O₂-3H₂O, Na(H₃O)(UO₂)₃(SeO₃)₂O₂-4H₂O, or a combination thereof. In some embodiments, the green-emitting phosphor is selected from the group consisting of compositions of formula (A70). In some embodiments, in formula (A70), A is Na, K, or a combination thereof and M is Si, Ti, or a combination thereof. In some embodiments, the phosphor of formula (A70) is K₂SiF₆:U⁶⁺.

Examples of the green-emitting phosphor of formula (A11) include UO₃-0.75H₂O, UO₃—H₂O, UO₃—2H₂O, or a combination thereof. Examples of the green-emitting phosphor of formula (A12) include UO₄—2H₂O, UO₄—4H₂O, or a combination thereof. Examples of the green-emitting phosphor of formula (A13) include UO₂CO₃, UO₂CO₃—H₂O, (UO₂)(CO₃)—2H₂O, or a combination thereof. Examples of the green-emitting phosphor of formula (A14) include U(UO₂)₃(PO₄)₂(OH)₆-2H₂O, U(UO₂)₃(PO₄)₂(OH)₆—4H₂O, or a combination thereof. Examples of the green-emitting phosphor of formula (A15) include Ca(UO₂)(CO₃)₂—3H₂O, Ca(UO₂)(CO₃)₂—5H₂O, or a combination thereof.

Other examples include, but are not limited to, HAl(UO₂)₄(AsO₄)₄—4OH₂O, H_{0.5}Al_{0.5}(UO₂)₂(PO₄)₂-8H₂O, Cu(UO₂)₂(SO₄)₂(OH)₂-8H₂O, K₂Ca₃[(UO₂)(CO₃)₃]₂-7H₂O, Na₇(UO₂)(SO₄)₄(SO₃OH)—3H₂O, Ca₂Ba₄[(UO₂)₃O₂(PO₄)₂]₃-16H₂O, NaAl(UO₂)₂(SO₄)₄- 18H₂O, Na₂Mg(UO₂)₂(SO₄)₄-18H₂), Na₇(UO₂)(SO₄)₄Cl—2H₂), (K,Na)(UO₂)SiO₃OH)—1.5H₂O, Ca(UO₂)₂[SiO₃(OH)]₂-5H₂O, Ca(UO₂)₃(MoO₄)₃(OH)₂-11H₂), Al₂(UO₂)(PO₄)₂(OH)₂-8H₂O, Al₃(UO₂)(PO₄)₃(OH)₂-13H₂O, Al(UO₂)₃(PO₄)₂(OH)₃-5.5H₂O, Al₂(UO₂)₃(PO₄)₂(OH)₆-10H₂O, Ca(UO₂)₄(SO₄)₂(OH)₆-6H₂O, K(UO₂)₂(SO₄)(OH)₃—H₂O, H₂Pb₃(UO₂)₆O₄(PO₄)₄-12H₂O, Na₄(UO₂)(SO₄)₃-3H₂O, Ca(UO₂)₃(CO₃)₂O₂-6H₂O, Ca[(UO₂)₂Si₅O₁₂(OH)₂]—3H₂O, (UO₂)₃(SeO₃)₂(OH)₂-5H₂O, (U)₂(UO₂)₄O₆(OH)₄-9H₂O, (UO₂)₈(SO₄)(OH)₁₄-3H₂O, (UO₂)₈(SO₄)(OH)₁₀-5H₂), Y₂U₄(CO₃)₃O₁₂-14.5H₂O, Mg(UO₂)₂(SO₄)O₂-3.5H₂), Pb[(UO₂)₃O₃(OH)₂]3H₂O, Pb_{1.5}[(UO₂)₁₀)O₆(OH)₁₁]—11H₂), Na₅(UO₂)(SO₄)₃(SO₃OH)—H₂O, Ca(UO₂)₂Si₆O₁₅-5H₂O, PbU₇O₂₂-12H₂), Ca₂Cu(UO₂)(CO₃)₄-6H₂O, (H₃O)₃KCa(UO₂)₇O₄(PO₄₄-8H₂), (H₃O)₄Ca₂(UO₂)₂(PO₄)₄-5H₂), Ca₃Mg₃(UO₂)₂(CO₃)₆(OH)₄-8H₂); HAl(UO₂)PO₄(OH)₃-4H₂), [(UO₂)₈O₂(OH)₁₂]—12H₂O, NaCa₃(UO₂)(SO₄)(CO₃)₃F—10H₂O, Ca(UO₂)₆(CO₃)₅(OH)₄-6H₂), (UO₂)₂(SO₄)₂-5H₂O, (H₃O)₂Mg(UO₂)₂(SiO₄)₂-4H₂O, (UO₂)₂SiO₄-2H₂), (Na,K)(UO₂)SiO₃(OH)—1.5H₂O, (H₃O)(UO₂)(AsO₄)—3H₂), (UO₂)₆(SO₄)O₂(OH)₆-14H₂), Al_{0.5-1}(UO₂)₄(PO₄)₄-(20-21)H₂O(F<1), (Mg,Ca)₄(UO₂)₄(Si₂O₅)_{5.5}(OH)₅-13H₂O, Cu(UO₂)(OH)₄, (K,Ba,Ca)₂(UO₂)₂Si₅O₁₃—H₂O, K₂Ca(UO₂)₇(PO₄)₄(OH)₆-6H₂O, Zn₂(UO₂)₆(SO₄)₃(OH)₁₀-16H₂), CaZn₁₁(UO₂)(CO₃)₃(OH)₂₀-4H₂O or a combination thereof.

The green-emitting phosphors disclosed herein may absorb radiation in the near-UV or blue region (a wavelength range between about 400 nm and 470 nm) and emit in a narrow region with an emission peak centered in a wavelength range from about 510 nm to about 540 nm, particularly from about 520 nm to about 530 nm. In some embodiments, these phosphors may be utilized in a phosphor blend to produce white light. These narrow green-emitting phosphors may be useful in display applications, in particular.

In some embodiments, an activator ion may be present in the green emitting phosphor such as Mn²⁺, Mn⁴⁺, Ce³⁺, Sn²⁺, Bi³⁺, Sb³⁺, Cr³⁺, Tb³⁺, Pr³⁺, Eu³⁺, Ti⁴⁺, In⁺, Tl⁺, Dy³⁺ and Pb²⁺.

Devices of the present disclosure may be used as lighting and backlight apparatuses for general illumination and display applications. Examples include chromatic lamps, plasma screens, xenon excitation lamps, UV excitation marking systems, automotive headlamps, home and theatre projectors, laser pumped devices, point sensors, liquid crystal display (LCD) backlight units, televisions, computer monitors, mobile phones, smartphone, tablet computers and other handheld devices that have a display including an LED source as described herein. The list of these applications is meant to be merely exemplary and not exhaustive.

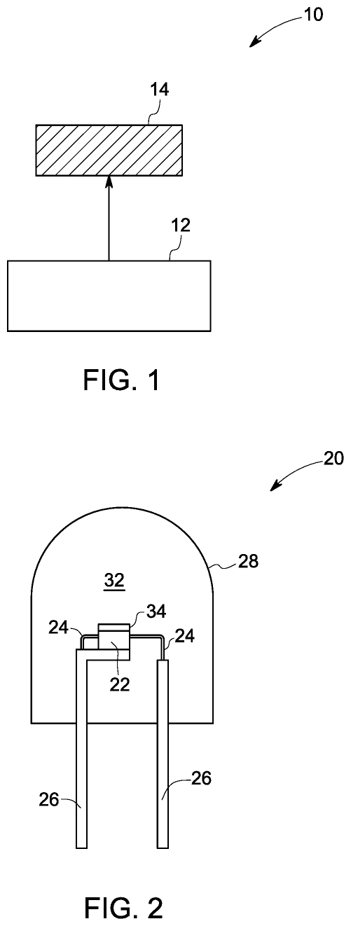

FIG. 1 show a device 10, according to one embodiment of the present disclosure. The device 10 includes a LED light source 12 and a phosphor material 14 including a green-emitting phosphor as described above in the present disclosure. The LED light source 12 may comprise a UV or blue emitting LED. In some embodiments, the LED light source 12 produces blue light in a wavelength range from about 440 nm to about 460 nm. In the device 10, the phosphor material 14 including the green-emitting phosphor as described herein, is optically coupled to the LED light source 12. Optically coupled means that radiation from the LED light source 12 is able to excite the phosphor material 14, and the phosphor material 14 is able to emit light in response to the excitation by the radiation. The phosphor material 14 may be disposed on a part of the LED light source 12 or located remotely at a distance from the LED light source 12.

The LED light source may be an inorganic LED light source or an organic LED light source. The term ‘LED light source’, as used herein, is meant to encompass all LED light sources such as semiconductor laser diodes (LD), inorganic light emitting diodes, organic light emitting diodes (OLED) or a hybrid of LED and LD. Further, it should be understood that the LED light source may be replaced, supplemented or augmented by another radiation source unless otherwise noted and that any reference to semiconductor, semiconductor LED, or LED chip is merely representative of any appropriate radiation source, including, but not limited to, LDs and OLEDs.

In some embodiments, the phosphor material 14 additionally includes a red emitting phosphor of formula I: A₂[MF₆]:Mn⁴⁺, where A is Li, Na, K, Rb, Cs, or a combination thereof; and M is Si, Ge, Sn, Ti, Zr, Al, Ga, In, Sc, Hf, Y, La, Nb, Ta, Bi, Gd, or a combination thereof. The red emitting phosphor of formula I is optically coupled to the LED light source 12. The phosphors of formula I are described in U.S. Pat. Nos. 7,497,973, and 8,906,724, and related patents assigned to the General Electric Company.

Examples of the red emitting phosphors of formula I include K₂[SiF₆]:Mn⁴⁺, K₂[TiF₆]:Mn⁴⁺, K₂[SnF₆]:Mn⁴⁺, Cs₂[TiF₆]:Mn⁴⁺, Rb₂[TiF₆]:Mn⁴⁺, Cs₂[SiF₆]:Mn⁴⁺, Rb₂[SiF₆]:Mn⁴⁺, Na₂[TiF₆]:Mn⁴⁺, Na₂[ZrF₆]:Mn⁴⁺, K₃[ZrF₇]:Mn⁴⁺, K₃[BiF₇]:Mn⁴⁺, K₃[YF₇]:Mn⁴⁺, K₃[LaF₇]:Mn⁴⁺, K₃[GdF₇]:Mn⁴⁺, K₃[NbF₇]:Mn⁴⁺ or K₃[TaF₇]:Mn⁴⁺. In certain embodiments, the phosphor of formula I is K₂SiF₆:Mn⁴⁺.

The phosphor material 14 may be present in any form such as powder, glass, composite e.g., phosphor-polymer composite or phosphor-glass composite. Further, the phosphor material 14 may be used as a layer, sheet, strip, dispersed particulates, or a combination thereof. In some embodiments, the phosphor material 14 includes the green-emitting phosphor in glass form. In some of these embodiments, the device 10 may include the phosphor material 14 in form of a phosphor wheel (not shown in figures). The phosphor wheel may include the green-emitting phosphor in glass form. A phosphor wheel and related devices are described in a previously filed patent application Serial No. PCT/US17/31654.

In some embodiments, the device 10 may be a backlight unit for display applications. In these embodiments, the phosphor material 14 including the green-emitting phosphor, may be present in form of a sheet or strip that is mounted or disposed on a surface of the LED light source 12. A backlight unit and related devices are described in a previously filed patent application Ser. No. 15/370762.

FIG. 2 illustrates a lighting apparatus or lamp 100, in accordance with some embodiments. The lighting apparatus 100 includes an LED chip 22, and leads 24 electrically attached to the LED chip 22. The leads 24 may comprise thin wires supported by a thicker lead frame(s) 26 or the leads 24 may comprise self supported electrodes and the lead frame may be omitted. The leads 24 provide current to LED chip 22 and thus cause it to emit radiation.

The LED chip 22 may be encapsulated within an envelope 28. The envelope 28 may be formed of, for example glass or plastic. The LED chip 22 may be enclosed by an encapsulant material 32. The encapsulant material 32 may be a low temperature glass, or a polymer or resin known in the art, for example, an epoxy, silicone, epoxy-silicone, acrylate or a combination thereof. In an alternative embodiment, the lighting apparatus 100 may only include the encapsulant material 32 without the envelope 28. Both the envelope 28 and the encapsulant material 32 should be transparent to allow light to be transmitted through those elements.

With continued reference to FIG. 2, a layer 30 of the phosphor material including the green-emitting phosphor as described herein is disposed on a surface 21 of the LED chip 22. The layer 30 may be disposed by any appropriate method, for example using a slurry prepared by mixing silicone and the phosphor material. In one such method, a silicone slurry in which the particles of the phosphor material are randomly suspended, is placed around the LED chip 22. This method is merely exemplary of possible positions of the layer 30 and LED chip 22. As illustrated, the layer 30 may be disposed for example, coated over or directly on the surface 21 of the LED chip 22 by coating and drying the slurry over the LED chip 22. The surface 21 is a light emitting surface of the LED chip 22. The light emitted by the LED chip 22 mixes with the light emitted by the phosphor material of the layer 30 to produce desired emission.

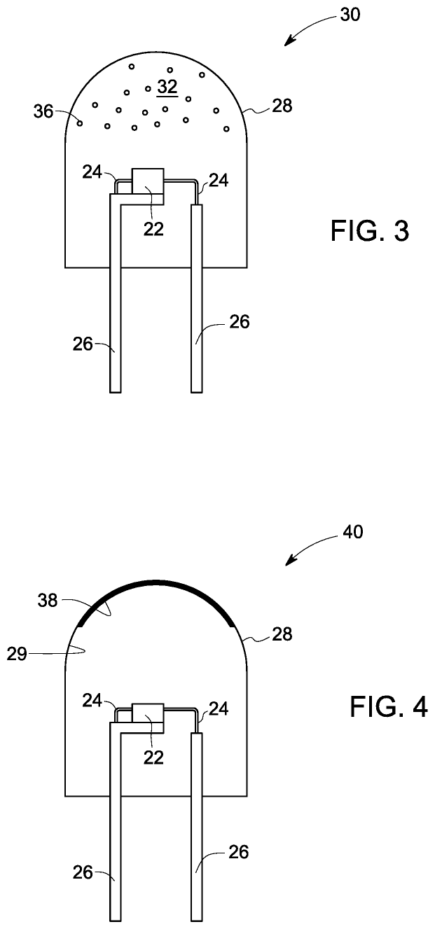

In some other embodiments, the phosphor material including green-emitting phosphor as described herein is interspersed within the encapsulant material 32, instead of being disposed directly on the LED chip 22 as shown in FIG. 2. FIG. 3 illustrates a lighting apparatus 300 that includes particulates 34 of the phosphor material interspersed within a portion of the encapsulant material 32. The particulates of the phosphor material may be interspersed throughout the entire volume of the encapsulant material 32. Blue light emitted by the LED chip 22 mixes with the light emitted by the particulates 34 of the phosphor material, and the mixed light transmits out from the lighting apparatus 200.

In some other embodiments, a layer 36 of the phosphor material including the green-emitting phosphor, is coated onto a surface of the envelope 28 as illustrated in FIG. 4, instead of being formed over the LED chip 22 (FIG. 2). As shown, the layer 36 is coated on an inside surface 29 of the envelope 28, although the layer 36 may be coated on an outside surface of the envelope 28, if desired. The layer 36 may be coated on the entire surface of the envelope 28 or only a top portion of the inside surface 29 of the envelope 28. The UV/blue light emitted by the LED chip 22 mixes with the light emitted by the layer 36, and the mixed light transmits out. Of course, the phosphor material may be located in any two or all three locations (as shown in FIGS. 2-4) or in any other suitable location, such as separately from the envelope 28 or integrated into the LED chip 22.

In any or all the above configurations, the lighting apparatus 100, 200, or 300 shown respectively in FIG. 2, FIG. 3 or FIG. 4 may also include a plurality of scattering particles (not shown), which are embedded in the encapsulant material 32. The scattering particles may comprise, for example, alumina, silica, zirconia, or titania. The scattering particles effectively scatter the directional light emitted from the LED chip 22, preferably with a negligible amount of absorption.

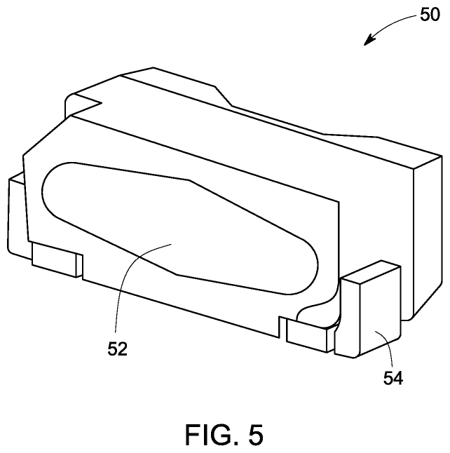

Some embodiments are directed to a backlight apparatus 50 as illustrated in FIG. 5. The backlight apparatus 50 includes a surface mounted device (SMD) type light emitting diode for backlight or display applications. This SMD is a “side-emitting type” and has a light-emitting window 52 on a protruding portion of a light guiding member 54. An SMD package may comprise an LED chip as defined above, and a phosphor material including the green-emitting phosphor as described herein. In some embodiments, the SMD package may comprise an LED chip as defined above, and a phosphor material including the green-emitting phosphor and a red-emitting Mn⁴⁺ doped phosphor of formula I as described herein.

In addition to the green-emitting phosphor and, optionally, the red-emitting Mn⁴⁺ doped phosphor of formula I, the phosphor material may further include one or more other luminescent materials. Additional luminescent materials such as blue, yellow, red, orange, or other color phosphors may be used in the phosphor material to customize the white color of the resulting light and produce specific spectral power distributions.

Suitable additional phosphors for use in the phosphor material include, but are not limited to:

((Sr_{1-z} (Ca, Ba, Mg, Zn)_{z})_{1-(x+w)}(Li, Na, K, Rb)_{w}Ceₓ)₃(Al_{1-y}Si_{y})O_{4+y+3(x-w)}F_{1-y-3(x-w)}, 0<x≤0.10, 0≤y≤0.5, 0≤z≤0.5, 0≤w≤x; (Ca, Ce)₃Sc₂Si₃O₁₂(CaSiG); (Sr,Ca,Ba)₃Al₁₋ₓSiₓO₄₊ₓF₁₋ₓ:Ce³⁺ (SASOF)); (Ba,Sr,Ca)₅(PO₄)₃(Cl,F,Br,OH):Eu²⁺,Mn²⁺; (Ba,Sr,Ca)BPO₅:Eu²⁺,Mn²⁺; (Sr,Ca)₁₀(PO₄)₆*vB₂O₃:Eu²⁺ (wherein 0<v≤1); Sr₂Si₃O₈*2SrCl₂:Eu²⁺; (Ca,Sr,Ba)₃MgSi₂O₈:Eu²⁺,Mn^{2+;}BaAl₈O₁₃:Eu²⁺; 2SrO*0.84P₂O₅*0.16B₂O₃:Eu²⁺; (Ba,Sr,Ca)MgAl₁₀O₁₇:Eu²⁺,Mn²⁺; (Ba,Sr,Ca)Al₂O₄:Eu²⁺; (Y,Gd,Lu,Sc,La)BO₃:Ce³⁺,Tb³⁺; ZnS:Cu⁺,Cl⁻; ZnS:Cu⁺,Al³⁺; ZnS:Ag⁺,Cl⁻; ZnS:Ag⁺,Al³⁺; (Ba,Sr,Ca)₂Si₁₋ₙO₄₋₂ₙ: Eu²⁺ (wherein 0≤n≤0.2); (Ba,Sr,Ca)₂(Mg,Zn)Si₂O₇:Eu²⁺; (Sr,Ca,Ba)(Al,Ga,In)₂S₄:Eu²⁺; (Y,Gd,Tb,La,Sm,Pr,Lu)₃(Al,Ga)₅₋ₐO_{12-3/2a}:Ce³⁺ (wherein 0≤a≤0.5); (Ca,Sr)₈(Mg,Zn)(SiO₄)₄Cl₂:Eu²⁺,Mn²⁺; Na₂Gd₂B₂O₇:Ce³⁺,Tb³⁺; (Sr,Ca,Ba,Mg,Zn)₂P₂O₇:Eu²⁺,Mn²⁺; (Gd,Y,Lu,La)₂O₃:Eu³⁺,Bi³⁺; (Gd,Y,Lu,La)₂O₂S:Eu³⁺,Bi³⁺; (Gd,Y,Lu,La)VO₄:Eu³⁺,Bi³⁺; (Ca,Sr)S:Eu²⁺,Ce³⁺; SrY₂S₄:Eu²⁺; CaLa₂S₄:Ce³⁺; (Ba,Sr,Ca)MgP₂O₇:Eu²⁺,Mn²⁺; (Y,Lu)₂WO₆:Eu³⁺,Mo⁶⁺; (Ba,Sr,Ca)_{b}Si_{g}Nₘ:Eu²⁺ (wherein 2b+4g=3m); Ca₃(SiO₄)Cl₂:Eu²⁺; (Lu,Sc,Y,Tb)₂₋ᵤ₋ᵥCeᵥCa₁₊ᵤLi_{w}Mg_{2-w}P_{w}(Si,Ge)_{3-w}O_{12-u/2} (where −0.5≤u≤1, 0<v≤0.1, and 0≤w≤0.2); (Y,Lu,Gd)₂₋ₘ (Y,Lu,Gd)CaₘSi₄N₆₊ₘC₁₋ₘ:Ce³⁺, (wherein (Lu,Ca,Li,Mg,Y), alpha-SiAlON doped with Eu²⁺ and/or Ce³⁺; Sr(LiAl₃N₄):Eu²⁺, (Ca,Sr,Ba)SiO₂N₂:Eu²⁺,Ce³⁺; beta-SiAlON:Eu²⁺, 3.5MgO*0.5MgF₂*GeO₂:Mn⁴⁺; Ca_{1-c-}Ce_{c}Eu_{f}Al_{1+c}Si_{1-c}N₃, (where 0≤c≤0.2, 0≤f≤0.2); Ca₁₋ₕ₋ᵣCeₕEuᵣAl₁₋ₕ (Mg,Zn)ₕSiN₃, (where 0≤h≤0.2, 0≤r≤0.2); Ca₁₋₂ₛ₋ₜCe₅(Li,Na)ₛEuₜAlSiN₃, (where 0≤s≤0.2, 0≤t≤0.2, s+t>0); (Sr, Ca)AlSiN₃: Eu²⁺,Ce³⁺, and Li₂CaSiO₄:Eu²⁺.

The ratio of each of the individual phosphors in the phosphor material may vary depending on the characteristics of the desired light output. The relative proportions of the individual phosphors in the various phosphor materials may be adjusted such that when their emissions are blended and employed in a device, for example a lighting apparatus, there is produced visible light of predetermined x and y values on the CIE chromaticity diagram.

Other additional luminescent materials suitable for use in the phosphor material may include electroluminescent polymers such as polyfluorenes, preferably poly(9,9-dioctyl fluorene) and copolymers thereof, such as poly(9,9′-dioctylfluorene-co-bis-N, N′-(4-butylphenyl)diphenylamine) (F8-TFB); poly(vinylcarbazole) and polyphenylenevinylene and their derivatives. In addition, the light emitting layer may include a blue, yellow, orange, green or red phosphorescent dye or metal complex, a quantum dot material, or a combination thereof. Materials suitable for use as the phosphorescent dye include, but are not limited to, tris(1-phenylisoquinoline) iridium (III) (red dye), tris(2-phenylpyridine) iridium (green dye) and Iridium (III) bis(2-(4,6-difluorephenyl)pyridinato-N,C2) (blue dye). Commercially available fluorescent and phosphorescent metal complexes from ADS (American Dyes Source, Inc.) may also be used. ADS green dyes include ADS060GE, ADS061GE, ADS063GE, and ADS066GE, ADS078GE, and ADS090GE. ADS blue dyes include ADS064BE, ADS065BE, and ADS070BE. ADS red dyes include ADS067RE, ADS068RE, ADS069RE, ADS075RE, ADS076RE, ADS067RE, and ADS077RE. Exemplary quantum dot materials are based on CdSe, ZnS or InP, including, but not limited to, core/shell luminescent nanocrystals such as CdSe/ZnS, InP/ZnS, PbSe/PbS, CdSe/CdS, CdTe/CdS or CdTe/ZnS. Other examples of the quantum dot materials include perovskite quantum dots such as CsPbX₃, where X is Cl, Br, I or a combination thereof.

By use of the embodiments described in the present disclosure, particularly the phosphor materials described herein, devices can be provided producing white light for display applications for example LCD backlight units, having high color gamut and high luminosity. Alternately, by use of the embodiments described in the present disclosure, particularly the phosphor materials described herein, devices can be provided producing white light for general illumination having high luminosity and high CRI values for a wide range of color temperatures of interest (2500 K to 10000 K).

While only certain features of the disclosure have been illustrated and described herein, many modifications and changes will occur to those skilled in the art. It is, therefore, to be understood that the appended claims are intended to cover all such modifications and changes as fall within the true spirit of the disclosure.

1. A device comprising an LED light source optically coupled to a phosphor material comprising a green-emitting phosphor selected from the group consisting of:
(A1). (A²⁺_{y}M¹⁺_{2-2y})(UO₂)₂(ZO₄)₂—xH₂, where M is NH₄, H₃O, Na, K, or a combination thereof; A is Fe, Co, Cu, Zn, Mg, Ca, Sr, Ba, Pb, or a combination thereof; Z is As, P, V or a combination thereof; 0≤y≤1 and 0≤x≤16;
(A2). M¹⁺(UO₂)(SO₄)(OH, F)—xH₂O, where M is K, Na, or a combination thereof; and 0≤x≤2;
(A3). (A²⁺_{2y}M¹⁺_{4-4y})(UO₂)(CO₃)₃—xH₂O, where M is Na, K, or a combination thereof; A is Mg, Ca, or a combination thereof; 0≤y≤1 and 0≤x≤18;
(A4). (A²⁺)(UO₂)₄(ZO₄)₂(OH, F)₄—xH₂O, where A is Ca, Pb, or a combination thereof; Z is As, P, or a combination thereof; and 0≤x≤7;
(A5). (A²⁺_{y}M¹⁺_{2-2y})(UO₂)₆O₄(OH, F)₆—xH₂O, where A is Ca, Ba, or a combination thereof; M is K; 0≤y≤1; and 0≤x≤8;
(A6). (M¹⁺)₂(UO₂)(SO₄)₂—xH₂O, where M is NH4, Na, or a combination thereof; and 0≤x≤3;
(A7). Al(UO₂)₂(ZO₄)₂(OH, F)—xH₂O, where Z is As, V, P, or a combination thereof; and 0≤x≤11;
(A8). (L²⁺_{2y}M¹⁺_{4-4y})(UO₂)₆(SO₄)₃(OH, F)₁₀—xH₂O, where L is Co, Ni, or a combination thereof; M is Na; 0≤y≤1 and 0≤x≤16;
(A9). (A²⁺)₂(UO₂)₃O₂(PO₄)₂—xH₂O, where A is Ca, Pb, or a combination thereof; and 0≤x≤7;
(A10). (A²⁺_{y}M¹⁺_{2-2y})(UO₂)₃(SeO₃)₂O₂—xH₂O, where M is Ba, Na, or a combination thereof; A is H₃O; 0≤x≤4 and 0≤y≤1;
(A11). UO₃—xH₂O where 0≤x≤2;
(A12). UO₄—xH₂O where 0≤x≤2;
(A13). UO₂CO₃—xH₂O, where 0≤x≤2;
(A14). U(UO₂)₃(PO₄)₂(OH, F)₆—xH₂O where 0≤x≤4;
(A15). Ca(UO₂)(CO₃)₂—xH₂O where 0≤x≤5;
(A16). HAl(UO₂)₄(AsO₄)₄—xH₂O where 0≤x≤40;
(A17). H_{0.5}Al_{0.5}(UO₂)₂(PO₄)₂—xH₂O where 0≤x≤8;
(A18). Cu(UO₂)₂(SO₄)₂(OH, F)₂—xH₂O where 0≤x≤8;
(A19). K₂Ca₃[(UO₂)(CO₃)₃]₂—xH₂O where 0≤x≤7;
(A20). Na₇(UO₂)(SO₄)₄(SO₃OH)—xH₂O where 0≤x≤3;
(A21). Ca₂Ba₄[(UO₂)₃O₂(PO₄)₂]₃—xH₂O where 0≤x≤16;
(A22). NaAl(UO₂)₂(SO₄)₄—xH₂O where 0≤x≤18;
(A23). Na₂Mg(UO₂)₂(SO₄)₄—xH₂O where 0≤x≤18;
(A24). Na₇(UO₂)(SO₄)₄Cl—xH₂O where 0≤x≤2;
(A25). (K,Na)(UO₂)(SiO₃OH)—xH₂O where 0≤x≤1.5;
(A26). Ca(UO₂)₂[SiO₃(OH, F)]₂—xH₂O where 0≤x≤5;
(A27). Ca(UO₂)₃(MoO₄)₃(OH, F)₂—xH₂O where 0≤x≤11;
(A28). Al₂(UO₂)(PO₄)₂(OH, F)₂—xH₂O where 0≤x≤8;
(A29). Al₃(UO₂)(PO₄)₃(OH, F)₂—xH₂O where 0≤x≤13;
(A30). Al(UO₂)₃(PO₄)₂(OH, F)₃—xH₂O where 0≤x≤5.5;
(A31). Al₂(UO₂)₃(PO₄)₂(OH, F)₆—xH₂O where 0≤x≤10;
(A32). Ca(UO₂)₄(SO₄)₂(OH, F)₆—xH₂O where 0≤x≤6;
(A33). K(UO₂)₂(SO₄)(OH, F)₃—xH₂O where 0≤x≤1;
(A34). H₂Pb₃(UO₂)₆O₄(PO₄)₄—xH₂O where 0≤x≤12;
(A35). Na₄(UO₂)(SO₄)₃—xH₂O where 0≤x≤3;
(A36). Ca(UO₂)₃(CO₃)₂O₂—xH₂O where 0≤x≤6;
(A37). Ca[(UO₂)₂Si₅O₁₂(OH, F)₂]—xH₂O where 0≤x≤3;
(A38). (UO₂)₃(SeO₃)₂(OH, F)₂—xH₂O where 0≤x≤5;
(A39). (U)₂(UO₂)₄O₆(OH, F)₄—xH₂O where 0≤x≤9;
(A40). (UO₂)₈(SO₄)(OH, F)₁₄—xH₂O where 0≤x≤13;
(A41). (UO₂)₆(SO₄)(OH, F)₁₀—xH₂O where 0≤≤5;
(A42). Y₂U₄(CO₃)₃O₁₂—xH₂O where 0≤x≤14.5;
(A43). Mg(UO₂)₂(SO₄)O₂—xH₂O where 0<x≤3.5;
(A44). Pb[(UO₂)₃O₃(OH, F)₂]—xH₂O where 0≤x≤3;
(A45). Pb₁₆[(UO₂)₁₀)O₆(OH, F)₁₁]—xH₂O where 0≤x≤11;
(A46). Nas(UO₂)(SO₄)₃(SO₃OH)—xH₂O where 0≤x≤1;
(A47). Ca(UO₂)₂Si₆O₁₆—xH₂O where 0≤x≤5;
(A48). PbU₇O₂₂—xH₂O where 0≤x≤12;
(A49). Ca₂Cu(UO₂)(CO₃)4—xH₂O where 0≤x≤6;
(A50). (H₃O)₃KCa(UO₂)₇O₄(PO₄)₄—xH₂O where 0≤x≤8;
(A51). (H₃O)₄Ca₂(UO₂)₂(PO₄)₄—xH₂O where 0≤x≤5;
(A52). Ca₃Mg₃(UO₂)₂(CO₃)₆(OH, F)₄—xH₂O where 0≤≤18;
(A53). HAI(UO₂)PO₄(OH, F)₃—xH₂O where 0≤x≤4;
(A54). [(UO₂)₈O₂(OH, F)₁₂]—xH₂O where 0≤x≤12;
(A55). NaCa₃(UO₂)(SO₄)(CO₃)₃F —xH₂O where 0≤x≤10;
(A56). Ca(UO₂)₆(CO₃)₆(OH, F)₄—xH₂O where 0≤x≤6;
(A57). (UO₂)₂(SO₄)₂—xH₂O where 0≤x≤5;
(A58). (H₃O)₂Mg(UO₂)₂(SiO₄)₂—xH₂O where 0≤x≤4;
(A59). (UO₂)₂SiO₄—xH₂O where 0≤x≤2;
(A60). (Na,K)(UO₂)SiO₃(OH, F)—xH₂O where 0≤≤1.5;
(A61). (H₃O)(UO₂)(AsO₄)—xH₂O where 0≤x≤3;
(A62). (UO₂)₆(SO₄)O₂(OH, F)₆—xH₂O where 0≤x≤14;
(A63). Al_{1-0.5}(UO₂)(PO₄)₂—xH₂O(F≤1) where 0≤x≤21;
(A64). (Mg,Ca)₄(UO₂)₄(Si₂O₅)_{5.5}(OH, F)₅—xH₂O where 0≤x≤13;
(A65). Cu(UO₂)(OH, F)₄;
(A66). (K,Ba,Ca)₂(UO₂)₂Si₅O₁₃—xH₂O where 0≤x≤1;
(A67). K₂Ca(UO₂)₇(PO₄)₄(OH, F)₆—xH₂O where 0≤x≤6;
(A68). Zn₂(UO₂)₆(SO₄)₃(OH, F)₁₀—xH₂O where 0≤x≤16;
(A69). CaZn₁₁(UO₂)(CO₃)₃(OH, F)₂O—xH₂O where 0≤x≤4;
(A70) AₓMF_{y}:U⁶⁺, where A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof; x is an absolute value of a charge of the [MF_{y}] ion; and y is 5, 6, or 7; and combinations thereof.

2. The device according to claim 1, wherein the green-emitting phosphor of group (A1) comprises:
Na₂(UO₂)₂(AsO₄)₂—5H₂O,
K₂(UO₂)₂(AsO₄)₂—6H₂O,
Ba(UO₂)₂(AsO₄)₂(10-12) H₂O,
Co(UO₂)₂(AsO₄)₂—8H₂O,
Cu(UO₂)₂(AsO₄)₂—8H₂O,
Cu(UO₂)₂(AsO₄)₂-12H₂O,
Zn(UO₂)₂(AsO₄)₂-10H₂O,
Mg(UO₂)₂(AsO₄)₂-(4-8)H₂O,
Mg(UO₂)₂(AsO₄)₂-(10-12)H₂O,
Ca(UO₂)₂(AsO₄)₂-8H₂O,
Ca(UO₂)₂(AsO₄)₂-10H₂O,
Ba(UO₂)₂(AsO₄)₂-8H₂O,
Ba(UO₂)₂(AsO₄)₂-(10-12)H₂O,
(NH₄, H₃O)₂(UO₂)₂(ASO₄, PO₄)₂-6H₂O,
(NH₄)₂(UO₂)₂(PO₄)₂-6H₂O,
(H₃O)₂(UO₂)₂(PO₄)₂-6H₂O,
Na₂(UO₂)₂(PO₄)₂-(6-8)H₂O,
Na₂(UO₂)₂(PO₄)₂-(10-16)H₂O,
K₂(UO₂)₂(PO₄)₂-6H₂O,
Fe(UO₂)₂(PO₄)₂-8H₂O,
Mg(UO₂)₂(PO₄)₂-8H₂O,
Mg(UO₂)₂(PO₄)₂—10H₂O,
Ca(UO₂)₂(PO₄)₂-(2-6)H₂O,
Ca(UO₂)₂(PO₄)₂-11H₂O,
Ba(UO₂)₂(PO₄)₂-6H₂O,
Ba(UO₂)₂(PO₄)₂-8H₂O,
Ba(UO₂)₂(PO₄)₂-12H₂O,
Pb(UO₂)₂(PO₄)₂-4H₂O,
Na₂(UO₂)₂(VO₄)₂-6H₂O,
K₂(UO₂)₂(VO₄)₂-(1-3)H₂O,
Ca(UO₂)₂(VO₄)₂-3H₂O,
Ca(UO₂)₂(VO₄)₂-(5-8)H₂O, or a combination thereof.

3. The device according to claim 1, wherein the green-emitting phosphor of group (A2) comprises:
K(UO₂)(SO₄)(OH)—H₂O,
Na(UO₂)(SO₄)(OH)—2H₂O, or a combination thereof.

4. The device according to claim 1, wherein the green-emitting phosphor of group (A3) comprises:
K₄(UO₂)(CO₃)₃,
Na₄(UO₂)(CO₃)₃,
Na₂Ca(UO₂)(CO₃)₃—6H₂O,
Mg₂(UO₂)(CO₃)₃-18H₂O,
CaMg(UO₂)(CO₃)₃—12H₂O,
Ca₂(UO₂)(CO₃)₃-11H₂O, or a combination thereof.

5. The device according to claim 1, wherein the green-emitting phosphor of group (A4) comprises:
Ca(UO₂)₄(ASO₄)₂(OH)₄-6FH₂O,
Pb(UO₂)₄(PO₄)₂(OH)₄—7H₂O, or a combination thereof.

6. The device according to claim 1, wherein the green-emitting phosphor of group (A5) comprises:
K₂(UO₂)₆O₄(OH)₆-7H₂O,
Ca(UO₂)₆O₄(OH)₆-8H₂O,
Ba(UO₂)₆O₄(OH)₆-8H₂O, or a combination thereof.

7. The device according to claim 1, wherein the green-emitting phosphor of group (A6) comprises:
(NH₄)₂(UO₂)(SO₄)₂-2H₂O,
Na₂(UO₂)(SO₄)₂-3H₂O, or a combination thereof.

8. The device according to claim 1, wherein the green-emitting phosphor of group (A7) comprises:
Al(UO₂)₂(AsO₄)₂(F,OH)—6.5H₂O,
Al(UO₂)₂(VO₄)₂(OH)—8H₂O,
Al(UO₂)₂(VO₄)₂(OH)—11H₂O,
Al(UO₂)₂(PO₄)₂(OH)—8H₂O, or a combination thereof.

9. The device according to claim 1, wherein the green-emitting phosphor of group (A8) comprises:
Co₂(UO₂)₆(SO₄)₃(OH)₁₀-16H₂O,
Ni₂(UO₂)₆(SO₄)₃(OH)₁₀-16H₂O,
Na₄(UO₂)₆(SO₄)₃(OH)₁₀—4H₂O, or a combination thereof.

10. The device according to claim 1, wherein the green-emitting phosphor of group (A9) comprises:
Pb₂(UO₂)₃O₂(PO₄)₂-5H₂O,
Ca₂(UO₂)₃O₂(PO₄)₂-7H₂O, or a combination thereof.

11. The device according to claim 1, wherein the green-emitting phosphor of group (A10) comprises:
Ba(UO₂)₃(SeO₃)₂O₂-3H₂O,
Na(H₃O)(UO₂)₃(SeO₃)₂O₂-4H₂O, or a combination thereof.

12. The device according to claim 1, wherein the green-emitting phosphor of group (A70) comprises K₂SiF₆:U⁶⁺.

13. The device according to claim 1, wherein the phosphor material additionally comprises a phosphor of formula I
AₓMF_{y}:Mn⁴⁺ I
wherein
A is Li, Na, K, Rb, Cs, or a combination thereof;
M is Si, Ge, Sn, Ti, Zr, Al, Ga, In, Sc, Hf, Y, La, Nb, Ta, Bi, Gd, or a combination thereof;
x is an absolute value of a charge of the M F_{y} ion; and
y is 5, 6 or 7.

14. The device according to claim 13, wherein the phosphor of formula I is K₂SiF₆:Mn⁴⁺.

15. A lighting apparatus comprising the device of claim 1.

16. A backlight apparatus comprising the device of claim 1.

17. A television comprising the backlight apparatus of claim 16.

18. A mobile phone comprising the backlight apparatus of claim 16.

19. A computer monitor comprising the backlight apparatus of claim 16.
